(19) United States
(12) Patent Application Publication
(10) Pub. No.: US 2020/0300914 A1
(43) Pub. Date: Sep. 24, 2020

(54) CIRCUITRY DESIGN METHOD AND STORAGE MEDIUM

(71) Applicants: Kabushiki Kaisha Toshiba, Tokyo (JP); Toshiba Electronic Devices & Storage Corporation, Tokyo (JP)

(72) Inventors: Yuki Watanabe, Funabashi Chiba (JP); Masato Nakazato, Kawasaki Kanagawa (JP)

(21) Appl. No.: 16/541,277

(22) Filed: Aug. 15, 2019

(30) Foreign Application Priority Data
Mar. 20, 2019 (JP) 2019-053313

(51) Int. Cl. G01R 31/3185

(52) U.S. Cl. CPC G01R 31/318536; G01R 31/318558; G01R 31/318572

(57) ABSTRACT

According to one embodiment, there is provided a circuitry design method. The method includes determining flip-flops for use in constituting a wrapper logic, based on a netlist of circuitry, and forming, after the determining, a multi-bit flip-flop including the flip-flops for use in constituting the wrapper logic, such that a flip-flop which is not used in constituting the wrapper logic is not included in the multi-bit flip-flop.

### CROSS-REFERENCE TO RELATED APPLICATIONS

This application is based upon and claims the benefit of priority from Japanese Patent Application No. 2019-053313, filed Mar. 20, 2019, the entire contents of which are incorporated herein by reference.

### FIELD

Embodiments described herein relate generally to a circuitry design method and a storage medium.

### BACKGROUND

In general, in implementation of an LSI, a multi-bit flip-flop (hereinafter “MBFF”) is used from the standpoint of reduction in power. By putting a plurality of flip-flops together into the MBFF (i.e. by converting flip-flops into the MBFF), the number of signal lines for a clock, scan enable, etc. can be decreased, and the dynamic power and the area of use can be reduced. In designing an LSI, the conversion of flip-flops into the MBFF is performed at a time of logical synthesis with a high conversion ratio.

On the other hand, there is a case where a wrapper logic is implemented for a hierarchical scan or a logic built-in self-test (LBIST). The wrapper logic is a boundary logic for shutting off an influence of the inside and outside of hierarchy, and is generally formed by utilizing existing FFs (including MBFFs) as much as possible.

For example, when a shared wrapper logic, by which an MBFF for use in normal system operation is also used for a test, is to be implemented, if an element that cannot be used in constituting the wrapper logic is included in a part of the MBFF, the MBFF cannot become a wrapper logic. Thus, a new flip-flop or the like is added, and a dedicated wrapper logic is formed. In this case, a decrease occurs in the advantageous effects of the reduction in power and the reduction in area of use, which are obtained by the use of the MBFF and the sharing of the wrapper logic.

### BRIEF DESCRIPTION OF THE DRAWINGS

FIG. 1 is a view illustrating an example of a schematic configuration of an information processing apparatus which is used to implement a circuitry design method according to a first embodiment;

FIG. 2 is a view schematically illustrating concepts of logical synthesis and physical synthesis;

FIG. 3 is a view schematically illustrating a concept of circuitry in which a wrapper logic is implemented;

FIG. 4A is a view illustrating an example of a configuration of an MBFF;

FIG. 4B is a view illustrating another example of the configuration of the MBFF;

FIG. 5 is a view illustrating an example of a processing procedure by the circuitry design method according to the first embodiment;

FIG. 6A is a view illustrating a state in which an element other than a flip-flop is connected to an external terminal;

FIG. 6B is a view illustrating that a flip-flop for a wrapper logic needs to be added;

FIG. 7A is a view illustrating a state in which all elements connected to an external terminal are flip-flops;

FIG. 7B is a view illustrating that flip-flops connected to the external terminal are usable for a wrapper logic;

FIG. 8 is a view for explaining a flip-flop which can be used in constituting the wrapper logic, and a flip-flop which cannot be used in constituting the wrapper logic;

FIG. 9 is a view for explaining the formation of an MBFF which constitutes the wrapper logic, and the formation of an MBFF which does not constitute the wrapper logic;

FIG. 10 is a view for explaining that a wrapper chain or the like is connected to an MBFF which constitutes a wrapper logic, and that an internal scan chain is connected to an MBFF which does not constitute a wrapper logic;

FIG. 11 is a view for describing processing by general technology;

FIG. 12 is a view illustrating an example of a processing procedure by a circuitry design method according to a second embodiment; and

FIG. 13 is a view illustrating an example in which an MBFF is divided into two parts, and scan enable signal lines and scan chains, which are used in the respective parts, are separately formed.

### DETAILED DESCRIPTION

Hereinafter, embodiments will be described with reference to the accompanying drawings.

In general, according to one embodiment, there is provided a circuitry design method. The method includes determining flip-flops for use in constituting a wrapper logic, based on a netlist of circuitry, and forming, after the determining, a multi-bit flip-flop including the flip-flops for use in constituting the wrapper logic, such that a flip-flop which is not used in constituting the wrapper logic is not included in the multi-bit flip-flop.

### First Embodiment

To begin with, a first embodiment will be described.

(Configuration)

FIG. 1 is a view illustrating an example of a schematic configuration of an information processing apparatus which is used to implement a circuitry design method according to the first embodiment.

An information processing apparatus 100 illustrated in FIG. 1 is, for example, a computer, and includes an input device 1 to which a user inputs information; an output device 2 such as a display which displays information; a storage medium 3 such as a memory which stores programs and data; and a processor 4 which executes programs for causing the computer to realize various functions, and which performs various kinds of data processing.

For example, as various tools applied to semiconductor test facilitation design of a large-scale integrated circuit (LSI) or the like, a synthesis tool 11, a scan tool 12, etc. are prepared, and these tools are stored in the storage medium 3. These tools operate under the control of the processor 4. The processor 4 reflects information that is input from the input device 1 onto data that is used by the various tools, causes the output device 2 to display the information processed by the various tools, and causes the storage medium 3 to store the information processed by the various tools.

The synthesis tool 11 includes a function of performing logical synthesis, and also includes a function of performing physical synthesis.

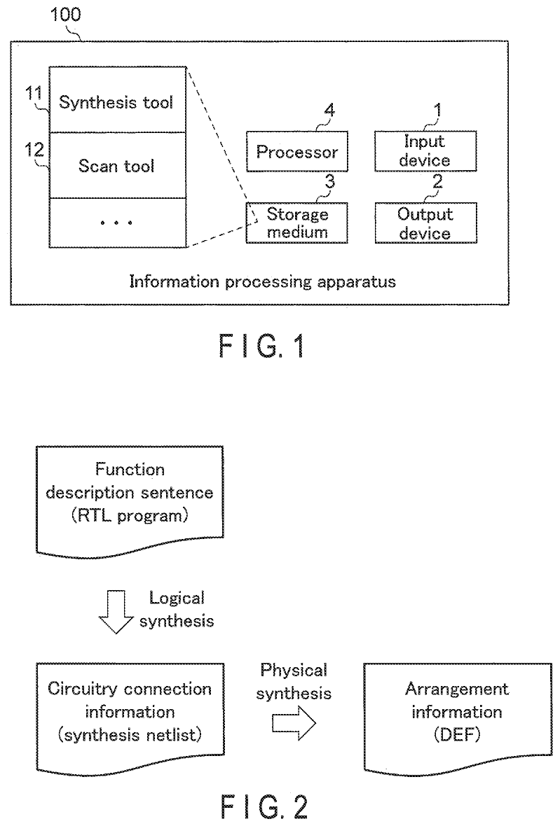

FIG. 2 schematically illustrates concepts of the logical synthesis and physical synthesis.

The synthesis tool 11 executes, by the logical synthesis, a development from a function description sentence of a register transfer level (RTL) (i.e. a program by RTL description) into circuitry connection information of a gate level (i.e. synthesis netlist). In addition, the synthesis tool 11 can generate, by the physical synthesis, arrangement information of design exchange format (DEF) description, which represents the physical arrangement positions of respective circuitry elements, from the synthesis netlist. The logical synthesis or physical synthesis is implemented by also taking into account the restriction conditions which a designer presets (restriction conditions of a chip area, power consumption, delay time, etc.)

Note that when it is preferable to add a change to the logical configuration of circuitry in consideration of the arrangement information generated by the physical synthesis, a corresponding part of the above-described function description sentence (program by RTL description) may be changed as needed, the logical synthesis may be executed once again to update the synthesis netlist, and the physical synthesis may further be executed to update the arrangement information of the DEF description.

On the other hand, the scan tool 12 illustrated in FIG. 1 generates, based on the synthesis netlist generated by the synthesis tool 11, a netlist (scan netlist) of circuitry in which a wrapper logic is formed and a scan enable signal line, a scan chain, etc. are added.

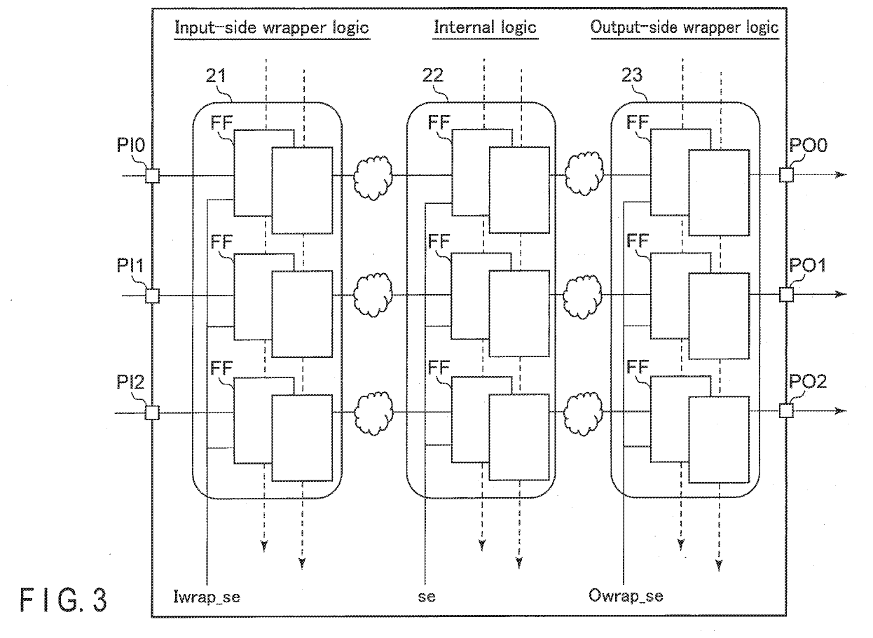

FIG. 3 schematically illustrates a concept of circuitry in which a wrapper logic is implemented.

As illustrated in FIG. 3, the circuitry in the chip includes a plurality of logics 21, 22, 23, . . . , which form a hierarchy. In this circuitry, wrapper logics are boundary logics for shutting off an influence of the inside and outside of the hierarchy at a time of a scan test. The wrapper logics include an input-side wrapper logic 21 which is provided on an input terminal side of a hierarchy block which accommodates the circuitry, and an output-side wrapper logic 23 which is provided on an output terminal side of the hierarchy block.

Each of the two wrapper logics 21 and 23 is constituted by using a multi-bit flip-flop (hereinafter “MBFF”). In addition, in some cases, an internal logic 22 disposed between the wrapper logics 21 and 23 is constituted by using an MBFF. Each MBFF is composed of a plurality of flip-flops.

The MBFF that constitutes the internal logic 22 is composed of a plurality of flip-flops which are connected between the flip-flops in the input-side wrapper logic 21 and the flip-flops in the output-side wrapper logic 23. The switching of signal inputs to the flip-flops in the internal logic 22 is controlled by a scan enable signal se for the internal logic.

On the other hand, the MBFF that constitutes the input-side wrapper logic 21 is composed of a plurality of flip-flops which are connected directly, or via combinational circuitry, to a plurality of input terminals PI0 to PI2. The switching of signal inputs to these flip-flops is controlled by a scan enable signal Iwrap_se for the input-side wrapper logic.

Furthermore, the MBFF that constitutes the output-side wrapper logic 23 is composed of a plurality of flip-flops which are connected directly, or via combinational circuitry, to a plurality of output terminals PO0 to PO2. The switching of signal inputs to these flip-flops is controlled by a scan enable signal Owrap_se for the output-side wrapper logic.

Note that the above-described scan enable signals se, Iwrap_se and Owrap_se are independently controlled on a logic-by-logic basis. A clock signal is identical to a clock signal of the internal logic in the case of a shared wrapper logic.

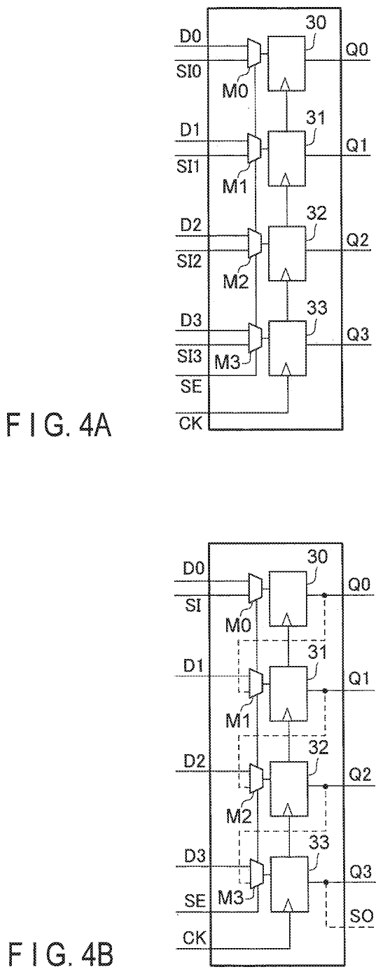

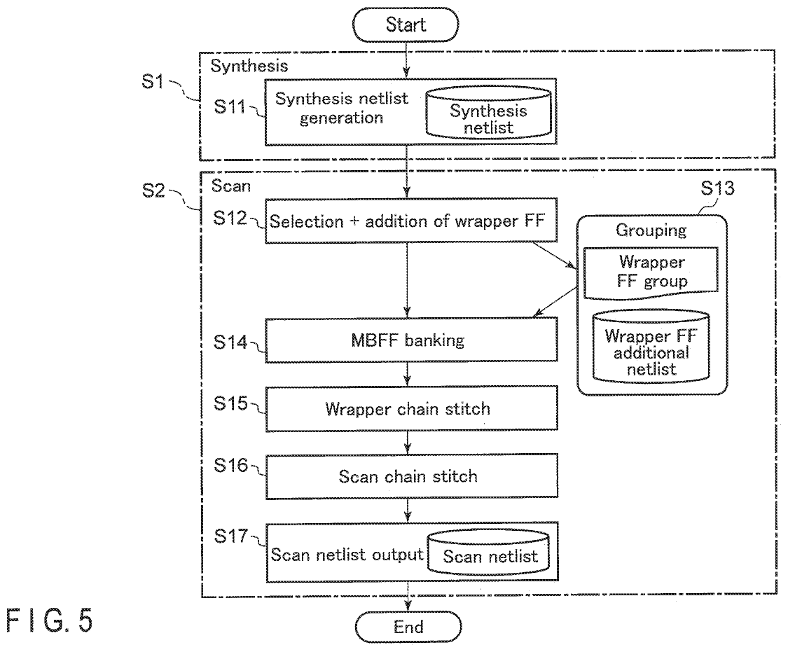

FIG. 4A and FIG. 4B illustrate examples of the configuration of the MBFF.

Each of FIG. 4A and FIG. 4B schematically illustrates an example of a configuration after conversion (MBFF banking) from flip-flops into the MBFF was already made.

As commonly illustrated in FIG. 4A and FIG. 4B, the MBFF includes flip-flops 30 to 33 and multiplexers (MUX) M0 to M3, which are connected in multiple stages. A clock signal, which is input from a CK port, is supplied to the flip-flops 30 to 33. A scan enable signal, which is input from an SE port, is supplied to the multiplexers (MUX) M0 to M3.

Note that the scan enable signal, which is input from the SE port, corresponds to the scan enable signal se when the MBFF constitutes the internal logic 22, corresponds to the scan enable signal Iwrap_se when the MBFF constitutes the input-side wrapper logic 21, and corresponds to the scan enable signal Owrap_se when the MBFF constitutes the outside-side wrapper logic 23.

In the example of FIG. 4A, in a normal operation mode, such a path is formed that data is input from D0 to D3 ports, is sent to the flip-flops 30 to 33 through the multiplexers M0 to M3, and is output from Q0 to Q3 ports. On the other hand, in a scan shift mode, such a path is formed that test data is input from SI0 to SI3 ports, is sent to the flip-flops 30 to 33 through the multiplexers M0 to M3, and is output from the Q0 to Q3 ports (identical to the ports used at the time of the normal operation mode).

In the example of FIG. 4B, in a normal operation mode, such a path is formed that data is input from D0 to D3 ports, is sent to the flip-flops 30 to 33 through the multiplexers M0 to M3, and is output from Q0 to Q3 ports. Specifically, the path is the same as in the example of FIG. 4A. On the other hand, in a scan shift mode, such a path is formed that test data is input from an SI port and then sent to the flip-flop 30 through the multiplexer M0, the test data output from the flip-flop 30 is sent to the flip-flop 31 via the multiplexer M1, the test data output from the flip-flop 31 is sent to the flip-flop 32 via the multiplexer M2, the test data output from the flip-flop 32 is sent to the flip-flop 33 via the multiplexer M3, and the test data output from the flip-flop 33 is output from an SO port. Specifically, the formed path of the scan chain is different from the path in FIG. 4A.

Depending on the purpose of use, either of the configurations illustrated in FIG. 4A and FIG. 4B may be adopted. For example, in consideration of an ambient environment of the arrangement location, an advantageous one of these configurations may be adopted. Furthermore, the configurations in FIG. 4A and FIG. 4B are illustrated by way of example, and the configurations are not limited to those in FIG. 4A and FIG. 4B.

(Operation)

Next, referring to FIG. 5, a description will be given of an example of a processing procedure by the circuitry design method according to the first embodiment.

To start with, a process of synthesis (step S1) is executed by the synthesis tool 11. Here, based on the program by RTL description, logical synthesis is executed, and a synthesis netlist is generated (step S1). In this synthesis process (step S1), conversion of flip-flops into an MBFF (MBFF banking) is not executed.

Next, a process (step S2) for enabling a scan test by the scan tool 12 is executed. Here, based on the synthesis netlist generated by the synthesis tool 11, a netlist (scan netlist) of circuitry, in which a wrapper logic is formed and a scan enable signal line, a scan chain, etc. are added, is generated. A concrete process of this will be described below.

In step S12, the netlist of circuitry generated by the synthesis tool 11 is analyzed, and a process of determining flip-flops, which constitute a wrapper logic (each of the input-side wrapper logic 21 and output-side wrapper logic 23), is executed.

The determination of flip-flops, which are used for constituting the wrapper logic, includes “selection” from existing flip-flops that are prepared in advance for the normal system operation, and “addition” of a new flip-flop.

The “addition” includes, for example, a process in which when any one of one or more elements, which are directly connected to an arbitrarily selected external terminal of a hierarchy block, is not a flip-flop, a new flip-flop that is connected closer to the external terminal side than any of these elements is added as a flip-flop for use in constituting the wrapper logic.

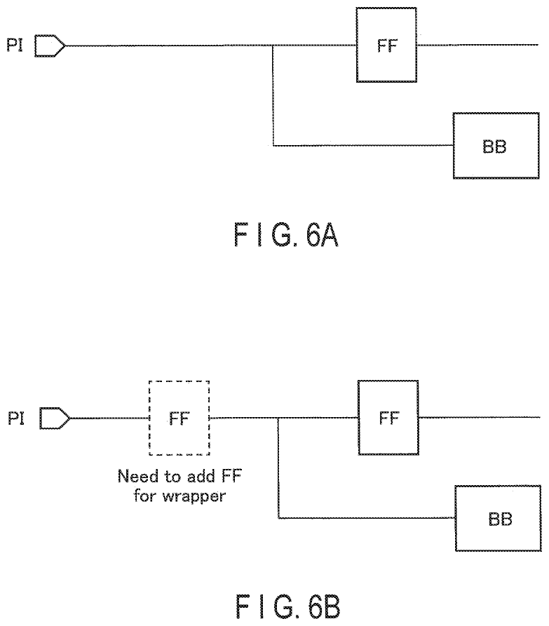

For example, as illustrated in FIG. 6A, when all elements connected to an input terminal PI of a hierarchy block are searched and the search result indicates that an element (e.g. an element corresponding to a black box (BB)) other than a flip-flop is present in addition to the flip-flop, it is deemed that a wrapper logic cannot be constituted by these elements. Then, as illustrated in FIG. 6B, a process of adding a new flip-flop, which is connected closer to the input terminal PI side than any of these elements, is executed. The flip-flop added here is a flip-flop that is newly added for the sole purpose of constituting a wrapper logic, and this flip-flop constitutes a dedicated wrapper logic in a process of a rear stage.

On the other hand, the “selection” includes a process in which when each of one or more elements, which are directly connected to an arbitrarily selected external terminal of a hierarchy block, is a flip-flop, each of these elements is selected as a flip-flop for use in constituting a wrapper logic.

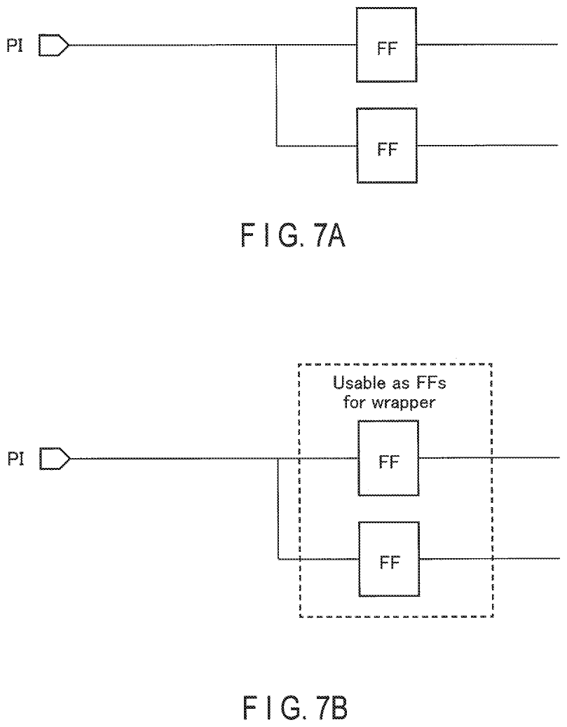

For example, as illustrated in FIG. 7A, when all elements connected to an input terminal PI of a hierarchy block are searched and the search result indicates that all elements are flip-flops, it is deemed that a wrapper logic can be constituted by these elements. Then, as illustrated in FIG. 7B, a process of selecting these elements as elements for use in constituting a wrapper logic is executed. The flip-flops selected here are existing flip-flops, and these flip-flops constitute a dedicated wrapper logic in a process of a rear stage.

Note that a flip-flop that is not used for a test is not a target of the above-described “selection” or “addition”.

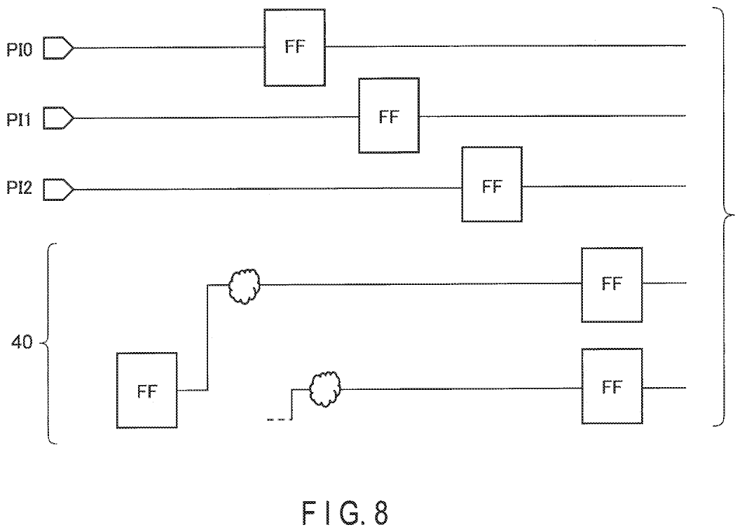

For example, as illustrated in FIG. 8, since the elements that are initially connected to input terminals PI0, PI1 and PI2 are only flip-flops, these flip-flops are treated as targets of selection as flip-flops for use in constituting the wrapper logic. However, flip-flops, which constitute a logic 40 that is not used for a test, are not used for constituting the wrapper logic, and do not become targets of the above-described “selection” or “addition”.

As described above, the wrapper logics include the input-side wrapper logic 21 and output-side wrapper logic 23. For example, a procedure may be adopted in which all elements connected to the output terminals of the hierarchy block are first searched and the flip-flops for use in constituting the output-side wrapper logic 23 are determined, and thereafter the flip-flops for use in constituting the input-side wrapper logic 21 are determined. In this case, the flip-flops which were determined as flip-flops for use in constituting the output-side wrapper logic 23 are excluded from the targets of flip-flops which are to be determined as flip-flops for use in constituting the input-side wrapper logic 21. By executing processing by the above procedure, since the number of branch paths decreases at the time of searching from the output terminal side of the hierarchy block, the load and time of the search process can be reduced.

In step S13, grouping is performed by using the information acquired by the process of step S12. In the grouping, the flip-flops that are used in constituting the wrapper logics (the input-side wrapper logic 21 and output-side wrapper logic 23) and the flip-flops that are not used in constituting the wrapper logics are grouped. Specifically, the grouping is performed to group the existing flip-flops selected for use in constituting the wrapper logics, the newly added flip-flops for use in constituting the wrapper logics, and the flip-flops that are not used in constituting the wrapper logics.

The information of flip-flops of each group formed by the grouping is collected as an additional netlist, and is used for forming each MBFF, as will be described later.

In step S14, using the information acquired in the process of step S13, the conversion (MBFF banking) of flip-flops into an MBFF is executed. Specifically, with respect to the individual groups formed by the grouping, the MBFF for constituting the input-side wrapper logic 21 and the MBFF for constituting the output-side wrapper logic 23 are formed. Besides, the MBFF for constituting the internal logic 22 or the like is formed. Each MBFF is formed by using, for example, flip-flops which are logically close to each other.

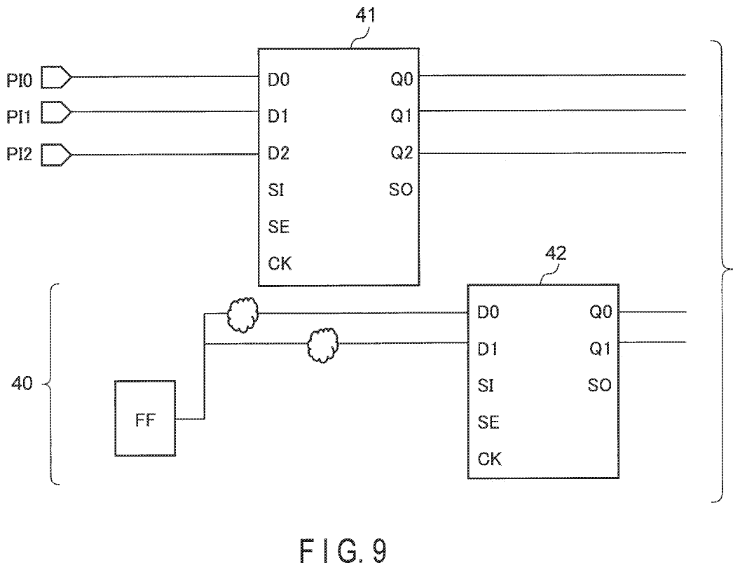

For example, as illustrated in FIG. 9, while an MBFF 41 which constitutes a wrapper logic is formed, an MBFF 42 which does not constitute a wrapper logic is formed. The MBFF 41 is configured such that the flip-flops connected to the input terminals PI0, PI1 and PI2 illustrated in the above-described FIG. 8 are formed into an MBFF. The MBFF 42 is configured such that the flip-flops included in the logic 40 illustrated in the above-described FIG. 8 are formed into an MBFF.

In the example of FIG. 9, the case of adopting the MBFF corresponding to the example of FIG. 4B is exemplarily illustrated. In each MBFF, ports of D0, D1, . . . , for data input, ports of Q0, Q1, . . . , for data output, an SI port for test data input, an SO port for test data output, an SE port for scan enable signal input, and a CK port for clock signal input are formed. In the process of step S14, the MBFF is formed for each of the groups formed by grouping. Thus, when an MBFF including flip-flops for use in constituting a wrapper logic is formed, it is possible to form the MBFF such that the MBFF does not include a flip-flop that is not used in constituting the wrapper logic.

In step S15, stitching of a scan chain (hereinafter “wrapper chain”) for a wrapper logic is executed for the MBFF that constitutes the wrapper logic. In step S16, stitching of a scan chain (hereinafter “internal scan chain”) for an internal logic is executed for the MBFF that constitutes the internal logic. Note that the order of processes of steps S15 and S16 may be reversed.

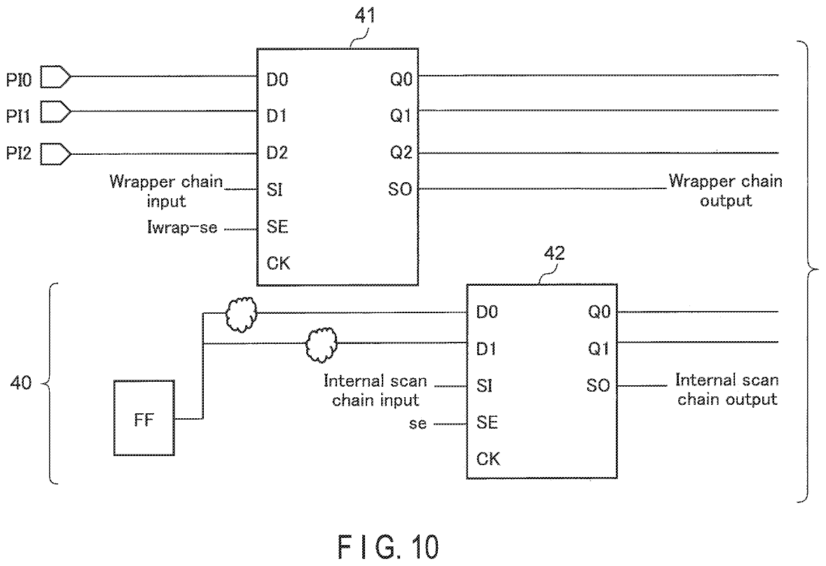

For example, as illustrated in FIG. 10, in the MBFF 41 that constitutes the wrapper logic, the wrapper chain is connected to the SI port and SO port. A line for inputting a scan enable signal Iwrap_se for the wrapper logic is connected to the SE port.

On the other hand, in the MBFF 42 that does not constitute a wrapper logic, the internal scan chain is connected to the SI port and SO port. A signal line for inputting a scan enable signal se for the internal logic is connected to the SE port.

In step S17, the information acquired in the process of steps S14 to S16 is collected as a scan netlist, and the scan netlist is output to the output device 2 or the like.

Note that, in FIG. 8 to FIG. 10, the example illustrated in FIG. 4A is adopted as the configuration of the MBFF. However, the configuration is not limited to this example. For example, the example illustrated in FIG. 4B may be adopted, and other configurations may be adopted.

In addition, in FIG. 8 to FIG. 10, the depiction of the configuration relating to the output-side wrapper logic 23 is omitted. Furthermore, since the configuration and process relating to the output-side wrapper logic 23 are similar to the configuration and process relating to the input-side wrapper logic 21, a description thereof is omitted.

In general technology, a plurality of flip-flops are first converted to an MBFF (MBFF banking), and then selection and addition of flip-flops necessary for constituting a wrapper logic are examined. In this case, there often occurs a process of adding a flip-flop which is normally unnecessary in the formation of the wrapper logic. For example, when a shared wrapper logic is to be implemented, if an element that cannot constitute a wrapper logic is included in a part of the MBFF, the MBFF cannot become the shared wrapper logic. Thus, a new flip-flop is added, and a dedicated wrapper logic is formed. In this case, a decrease occurs in the advantageous effects of the reduction in power and the reduction in area of use, which are obtained by the use of the MBFF and the sharing of the wrapper logic.

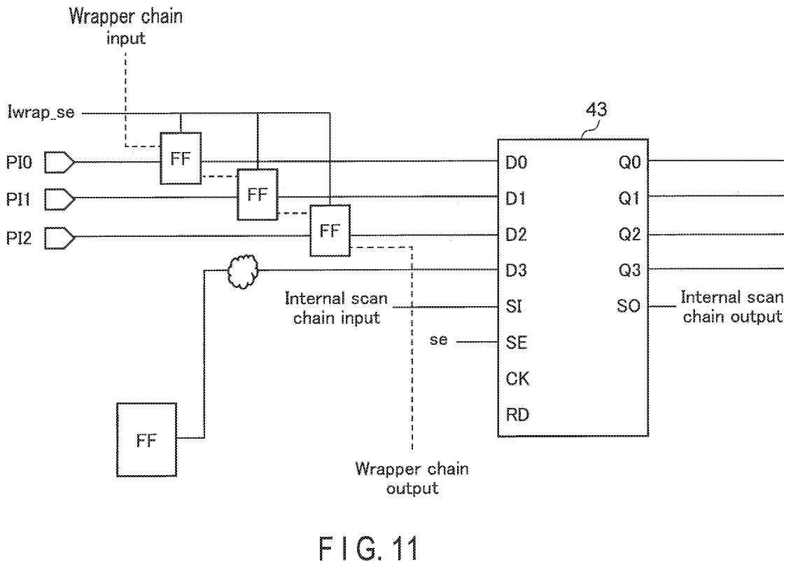

For example, as illustrated in FIG. 11, in general technology, if a bit (or a flip-flop or the like) corresponding to a D3 port, which cannot be used in constituting the wrapper logic, exists in a part of a formed MBFF 43 for a wrapper logic, this MBFF 43 cannot constitute a shared wrapper logic. In this case, it is necessary to add new flip-flops and multiplexers between the input terminals PI0 to PI2 and the D0 to D2 ports, and to add a stitch of the wrapper chain and a line of a scan enable signal.

By contrast, according to the present embodiment, after determining the flip-flops that are used for constituting the wrapper logic, a multi-bit flip-flop including the flip-flops for use in constituting the wrapper logic is formed such that a flip-flop that is not used for constituting the wrapper logic is not included. It is thus possible to reduce the occurrence of the situation in which a flip-flop or the like, which is normally unnecessary in the formation of the wrapper logic, is added. Therefore, it is possible to enhance the advantageous effects of the reduction in power and the reduction in area of use, which are obtained by the use of the MBFF and the sharing of the wrapper logic.

### Second Embodiment

Next, a second embodiment will be described. Hereinafter, a description of parts overlapping the first embodiment is omitted, and different parts will mainly be described.

The basic configuration is the same as illustrated in FIG. 1, etc. in the first embodiment, but the operation is different from that of the first embodiment.

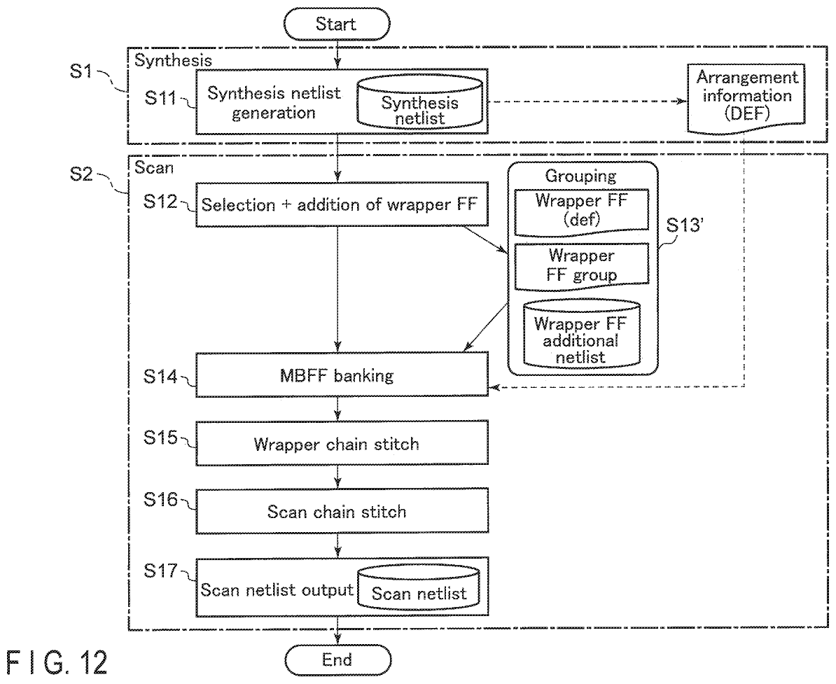

FIG. 12 illustrates an example of a processing procedure by a circuitry design method according to a second embodiment. This processing procedure differs from the processing procedure described in the first embodiment with reference to FIG. 5, in that arrangement information of DEF description representing the physical arrangement positions of respective circuitry elements is further generated in the synthesis process (step S1), and that information processing using this arrangement information is executed in the scan process (step S2).

In step S11, arrangement information (DEF) is generated by physical synthesis, from the synthesis netlist generated by logical synthesis.

In step S12, analysis using the arrangement information is performed, and a process of determining (selecting or adding) flip-flops, which constitute a wrapper logic, is executed.

In step S13′, arrangement information of DEF description (hereinafter “wrapper FF (def) information”) representing the physical arrangement positions of the flip-flips for use in constituting the wrapper logic is also generated by using the information acquired in the process of step S12.

In step S14, using the arrangement information acquired in the process of step S11 and the information including “wrapper FF (def) information” acquired in the process of step S13′, the conversion (MBFF banking) of flip-flops into MBFFs is executed. For example, when it has become clear, from the arrangement information and the wrapper FF (def) information, that there exists an MBFF in which a flip-flop and a flip-flop are physically spaced apart by a predetermined distance or more, this MBFF is de-banked. In addition, after the de-banking, banking may be performed once again.

In step S15, stitching of a wrapper chain is executed for the MBFF that constitutes the wrapper logic. In step S16, stitching of an internal scan chain is executed for the MBFF that constitutes the internal logic.

In step S17, the information acquired in the process of steps S14 to S16 is collected as a scan netlist, and the scan netlist is output to the output device 2 or the like.

According to the present embodiment, in addition to the advantageous effects obtained in the first embodiment, since the information processing using the arrangement information is executed, it is possible to understand, for example, the physical arrangement position of each flip-flop that is used in constituting the wrapper logic, and more suitable MBFF banking can be performed.

Hereinafter, a description will be given of modifications of the processes described in the first embodiment and the second embodiment.

[Modification 1]

A process may be performed in which, among the MBFFs formed in the process of MBFF banking of step S14, an arbitrarily selected MBFF (e.g. an MBFF including a flip-flop for use in constituting a wrapper logic) is divided into two parts, and scan enable signal lines and scan chains, which are used in the respective parts, are separately formed. This process is effective when the operations of the two parts are to be tested individually.

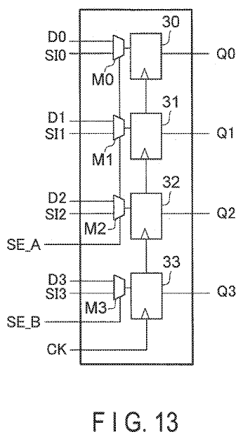

For example, when the MBFF corresponds to the configuration illustrated in the example of FIG. 4A, such a configuration may be adopted that, as illustrated in FIG. 13, the port SE is arranged by being divided into two ports SE_A and SE_B, a scan enable signal that is input from the port SE_A is supplied to the multiplexers (MUX) M0 to M2, and a scan enable signal that is input from the port SE_B is supplied to the multiplexer (MUX) M3. In this case, it is not necessary to make a change to the clock signal line of an input from the CK port.

[Modification 2]

When it turns out that, among the individual MBFFs formed in the process of the MBFF banking of step S14, an arbitrarily selected MBFF (e.g. an MBFF including a flip-flop for use in constituting a wrapper logic) includes a flip-flop that cannot be used in constituting the wrapper logic (i.e. only a part of flip-flops is a flip-flop that can be used in constituting the wrapper logic), a process of canceling (de-banking) the formation of this MBFF may be executed. This process is effective, for example, when a flip-flop that cannot be used in constituting the wrapper logic is unexpectedly included in the flip-flops for use in constituting the wrapper logic. After the above-described de-banking, banking may be executed once again.

[Modification 3]

In the synthesis process of step S1, a process of describing a matter, which specifies flip-flops for use in constituting the wrapper logic, in the program by RTL description that is the basis of the synthesis netlist, may be executed in advance. This process is effective when the flip-flops that are used in constituting the wrapper logic can be estimated in advance, or are clearly understood. This process can realize further facilitation of design, and further reduction in design time.

As described above in detail, according to the embodiments, it is possible to reduce the occurrence of the situation in which a flip-flop or the like, which is unnecessary in the formation of the wrapper logic, is added, and to improve the advantageous effect of the reduction in power and the reduction in area of use.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made. The accompanying claims and their equivalents are intended to cover such forms or modifications as would fall within the scope of the inventions.

1. A circuitry design method comprising:
determining flip-flops for use in constituting a wrapper logic, based on a netlist of circuitry; and
forming, after the determining, a multi-bit flip-flop including the flip-flops for use in constituting the wrapper logic, such that a flip-flop which is not used in constituting the wrapper logic is not included in the multi-bit flip-flop.

2. The circuitry design method according to claim 1, further comprising:
grouping i) the flip-flops for use in constituting the wrapper logic, and ii) the flip-flop which is not used in constituting the wrapper logic,
wherein each of results of the grouping is used in the forming of the multi-bit flip-flop.

3. The circuitry design method according to claim 1, wherein the determining of the flip-flops for use in constituting the wrapper logic includes:
selection from an existing flip-flop; and
addition of a new flip-flop.

4. The circuitry design method according to claim 3, wherein the selection includes selecting, when each of one or more elements connected directly to an arbitrarily selected external terminal is a flip-flop, each of the elements as a flip-flop which is used in constituting the wrapper logic.

5. The circuitry design method according to claim 3, wherein the addition includes adding, when any one of one or more elements connected directly to an arbitrarily selected external terminal is not a flip-flop, a new flip-flop which is connected closer to the external terminal than any of the elements, as a flip-flop which is used in constituting the wrapper logic.

6. The circuitry design method according to claim 3, further comprising:
grouping i) the existing flip-flop which is selected for use in constituting the wrapper logic, ii) the new flip-flop which is added for use in constituting the wrapper logic, and iii) the flip-flop which is not used in constituting the wrapper logic,
wherein each of results of the grouping is used in the forming of the multi-bit flip-flop.

7. The circuitry design method according to claim 1, wherein the forming of the multi-bit flip-flop includes forming the multi-bit flip-flop by using arrangement information of design exchange format (DEF) description which represents physical arrangement positions of respective circuitry elements.

8. The circuitry design method according to claim 1, further comprising:
cancelling, when the multi-bit flip-flop including flip-flops for use in constituting the wrapper logic includes a flip-flop which is not usable in constituting the wrapper logic, the forming of the multi-bit flip-flop.

9. The circuitry design method according to claim 1, further comprising:
dividing into two parts the multi-bit flip-flop including the flip-flops for use in constituting the wrapper logic, and separately forming scan enable signal lines and scan chains, which are used in the respective parts.

10. The circuitry design method according to claim 1, further comprising:
describing a matter, which specifies the flip-flops for use in constituting the wrapper logic, in a program by register transfer level (RTL) description, which is a basis of the netlist.

11. A non-transitory computer-readable storage medium having a program stored thereon which controls a computer to perform functions comprising:
determining flip-flops for use in constituting a wrapper logic, based on a netlist of circuitry; and
forming, after the determining, a multi-bit flip-flop including the flip-flops for use in constituting the wrapper logic, such that a flip-flop which is not used in constituting the wrapper logic is not included in the multi-bit flip-flop.

12. The storage medium according to claim 11, wherein the program controls the computer to further perform a function of grouping i) the flip-flops for use in constituting the wrapper logic, and ii) the flip-flop which is not used in constituting the wrapper logic,
wherein each of results of the grouping is used in the forming of the multi-bit flip-flop.

13. The storage medium according to claim 11, wherein the determining of the flip-flops for use in constituting the wrapper logic includes:
selection from an existing flip-flop; and
addition of a new flip-flop.

14. The storage medium according to claim 13, wherein the selection includes selecting, when each of one or more elements connected directly to an arbitrarily selected external terminal is a flip-flop, each of the elements as a flip-flop which is used in constituting the wrapper logic.

15. The storage medium according to claim 13, wherein the addition includes adding, when any one of one or more elements connected directly to an arbitrarily selected external terminal is not a flip-flop, a new flip-flop which is connected closer to the external terminal than any of the elements, as a flip-flop which is used in constituting the wrapper logic.

16. The storage medium according to claim 13, wherein the program controls the computer to further perform a function of grouping i) the existing flip-flop which is selected for use in constituting the wrapper logic, ii) the new flip-flop which is added for use in constituting the wrapper logic, and iii) the flip-flop which is not used in constituting the wrapper logic,
wherein each of results of the grouping is used in the forming of the multi-bit flip-flop.

17. The storage medium according to claim 11, wherein the forming of the multi-bit flip-flop includes forming the multi-bit flip-flop by using arrangement information of design exchange format (DEF) description which represents physical arrangement positions of respective circuitry elements.

18. The storage medium according to claim 11, wherein the program controls the computer to further perform a function of canceling, when the multi-bit flip-flop including flip-flops for use in constituting the wrapper logic includes a flip-flop which is not used in constituting the wrapper logic, the forming of the multi-bit flip-flop.

19. The storage medium according to claim 11, wherein the program controls the computer to further perform a function of dividing into two parts the multi-bit flip-flop including the flip-flops for use in constituting the wrapper logic, and separately forming scan enable signal lines and scan chains, which are used in the respective parts.

20. The storage medium according to claim 11, wherein the program controls the computer to further perform a function of describing a matter, which specifies the flip-flops for use in constituting the wrapper logic, in a program by register transfer level (RTL) description, which is a basis of the netlist.
